(19) United States
(12) Patent Application Publication
(10) Pub. No.: US 2026/0032994 A1
(43) Pub. Date: Jan. 29, 2026

(54) Multilevel converter system

(71) Applicant: PULSETRAIN GMBH, Karlshuld (DE)

(72) Inventor: Manuel Kuder, München (DE)

(21) Appl. No.: 19/100,053

(22) PCT Filed: Dec. 28, 2023
(86) PCT No.: PCT/EP2023/087945

§ 371 Date: Jan. 30, 2025

(30) Foreign Application Priority Data
Mar. 29, 2023 (DE) 10 2023 107 917.4

(51) Int. Cl. H10D 84/83; H02M 7/00; H02M 7/483; H10D 84/01; H10D 89/10

(52) U.S. Cl. CPC H10D 84/83125; H02M 7/003; H02M 7/483; H10D 84/0135; H10D 84/0144; H10D 89/10

(57) ABSTRACT

The invention relates to a multilevel converter system comprising a multiplicity of energy storage modules and transistors, wherein each energy storage module can be connected in parallel with the respective adjacent energy storage module, can be connected in series therewith and/or can be bridged and has at least one energy storage cell, wherein at least two adjacent NPN transistors share an N-type zone and/or wherein at least two adjacent PNP transistors share a P-type zone.

### CROSS-REFERENCE TO RELATED APPLICATION

This is a U.S. National Phase of International Patent Application No. PCT/EP2023/087945 filed Dec. 28, 2023, which claims the benefit of priority to German Patent Application No. 102023107917.4, filed Mar. 29, 2023.

### FIELD OF THE DISCLOSURE

The invention relates to a multilevel converter system comprising a multiplicity of energy storage modules and transistors, wherein each energy storage module can be connected in parallel with the respective adjacent energy storage module, can be connected in series therewith and/or can be bridged and has at least one energy storage cell.

### BACKGROUND

Previous energy storage devices are usually loaded with DC voltage (DC). This is due to the structure of conventional converter systems. An attempt is made to keep the AC voltage components, i.e. harmonic oscillations, away from the energy storage devices.

Since many energy storage devices have to be connected in series or in parallel in this case, a battery management system (BMS) is required. For example, a DC link capacitor can be connected downstream of the energy storage devices. This serves to further smooth the three-phase currents of the converter and to keep high-frequency oscillations away from the energy storage devices and to intercept switching overshoots since the inductance of the energy storage devices would continue to drive the current. The aim of this procedure is to load the energy storage devices with DC since it is assumed in this case that this contributes to the resistance of the battery cell and reduces the losses.

In a conventional electric vehicle for example, the converters which pass on the energy to the electric motor and deliver it to the battery again during braking energy recovery (recuperation) may be provided on the DC bus. Charging devices which can operate with AC voltage (AC) or DC voltage (DC) can also be connected to this bus, for example.

These converters are usually in the form of two-point converters, for example in the form of a B6 bridge in the case of a three-phase design, or—in particular in the field of solar installations—in the form of a three-point converter.

As an alternative to bridge circuits as converters, so-called multilevel converter systems are known.

Batteries, e.g. rechargeable batteries, can be used, for example, as energy storage devices or energy sources. The energy storage devices are not hard-wired to one another, but rather are combined as individual submodules. This structure is required for each phase. Therefore, the energy storage devices are divided among these phases and can be permanently connected in series or in parallel, for example.

For example, lithium-ion cells are often used in electric vehicles.

Present transistors are mostly constructed as NPN semiconductors. Thus, an area is negatively doped, then positively doped and then negatively doped again. This semiconductor with its three connections (drain, gate and source) is produced in a factory.

First, a silicon wafer is used to then turn it into many individual semiconductors using different process steps. These are then tested for their functionality and cut into individual discrete components. Each semiconductor—except for when it is used directly as a so-called “bare die”—is then given a housing in which the contact to the outside is made.

This procedure is advantageous in particular for present semiconductors (e.g. silicon MOSFETs, i.e. silicon metal-oxide-semiconductor field-effect transistors), since the gates are usually planar in power MOSFETs used for multilevel applications.

Due to the better switching and on-state behavior, power MOSFETs are usually constructed as so-called “superjunction MOSFETs”.

However, the market for power semiconductors has been disrupted by so-called “Wide Bandgap Devices” (WBG) for several years.

Two of them are particularly noteworthy, namely silicon carbide (SiC) and gallium nitride (GaN).

In the range of lower voltages, for example less than 650 V, GaN is expected to prevail according to the current situation. This is because GaN is more cost-effective and far more powerful than silicon components. However, these new switches are currently not constructed as planar components, but as lateral components.

Conventional multilevel converter systems are still comparatively expensive. This is due, for example, to the relatively high number of transistors. The transistors also require a relatively large amount of space, and so the chips used are relatively large, which has a negative impact on the production costs.

### SUMMARY

It is therefore an object of the invention to provide a multilevel converter system, a method for producing a multilevel converter system and a wafer for producing a multilevel converter system, in which the production costs of the multilevel converter system are reduced.

This object is achieved by the subjects as well as the method of the independent claims.

According to the invention, the, preferably modular, multilevel converter system comprises a multiplicity of energy storage modules and transistors.

A multilevel converter system describes a type of arrangement or wiring of a plurality of energy storage modules and/or transistors.

Each energy storage module can have at least one or exactly one battery, e.g. a rechargeable battery.

For example, the transistors serve as switches which can be used to select current and/or voltage paths, for example. As a result, the energy storage modules can be incorporated into or excluded from a desired configuration, for example.

At least or exactly two, three, four, five, six, seven, eight, nine, ten or more transistors are preferably assigned to each energy storage module.

The transistor may be designed, for example, for a voltage of less than 500 V, 400 V, 300 V, 200 V, 100 V, 50 V, 40 V, 30 V, 20 V or 10 V. The transistor can preferably be designed for a voltage of between 2 V and 8 V, for example 3 V, 4 V, 5 V, 6 V or 7 V.

For example, the transistor can be a lateral, planar or trench transistor. In principle, however, any types of construction are conceivable.

The transistor is preferably designed as a MOSFET or comprises a MOSFET.

MOSFETs can be switched at high frequencies.

At least one transistor may have a switching frequency of at least 1 Hz, for example.

Silicon, gallium nitride, gallium arsenide and/or silicon carbide may be provided as the semiconductor material, for example.

Each energy storage module can be connected in parallel with the respective adjacent energy storage module and/or can be connected in series therewith and/or can be bridged. Each energy storage module can preferably be connected in series with the respective adjacent energy storage module. The possibility of connection in parallel is advantageous, but not necessary.

The adjacent energy storage modules are preferably connected to each other via two current and/or voltage paths in each case. A transistor can be assigned to each path.

For example, three transistors are provided between two adjacent energy storage modules. As a result, the energy storage modules may be connected in parallel or in series, for example.

Each energy storage module has at least one energy storage cell.

For example, the energy storage module can have exactly one energy storage cell. Preferably, however, each energy storage module has a plurality of energy storage cells, e.g. at least 10, 20, 30, 40, 50, 60, 70, 80, 90 or 100. For example, at least 100 energy storage cells, e.g. 140, may be provided in an energy storage module.

The energy storage cells of an energy storage module can preferably be connected in parallel with each other. Preferably, the energy storage cells of an energy storage module are selected in such a way that the same charge as that applied to the grid is applied, e.g. 230 V.

Multilevel converter systems are much more versatile than bridge circuits. This allows almost any configurations to be created. For example, the energy storage modules can be connected to each other in any way, e.g. in parallel or in series. Individual energy storage modules can also be incorporated into or excluded from a desired configuration.

At least two adjacent NPN transistors share an N-type zone. Alternatively or additionally, at least two adjacent PNP transistors share a P-type zone.

N-type zones or P-type zones of adjacent transistors are thus combined.

Instead of two adjacent NPN transistors, this results in effectively an NPNPN transistor, or, instead of two adjacent PNP transistors, effectively a PNPNP transistor results.

Protection is also claimed for such transistors independently of a multilevel converter system.

As a result of the fact that N-type zones or P-type zones are saved, there are advantages in the required amount of semiconductor material in the case of adjacent switches, as is often the case with multilevel converter systems. On the one hand, this advantage is directly reflected in the price. On the other hand, the area of the chips is reduced, which also has a positive impact on the costs.

It was surprising that the saving and/or shared use of adjacent zones can be effected in multilevel converter systems and leads to a significant reduction in the costs there.

Developments of the invention can also be gathered from the dependent claims, the description and the accompanying drawings.

According to one embodiment, at least three NPN transistors are provided, wherein adjacent NPN transistors each share an N-type zone.

Alternatively or additionally, at least three PNP transistors are provided, wherein adjacent PNP transistors each share a P-type zone.

In principle, any number of transistors can be provided, adjacent transistors of which each share a zone.

For example, three NPN transistors can be combined to form an NPNPNPN transistor or three PNP transistors can be combined to form a PNPNPNP transistor.

According to another embodiment, the adjacent NPN transistors and/or PNP transistors are arranged side by side.

Preferably, the transistors are arranged linearly, i.e. in a row, and do not enclose an angle, for example.

According to another embodiment, the adjacent NPN transistors and/or PNP transistors are not arranged linearly to each other.

For example, the adjacent transistors may be oriented at right angles or obliquely to each other.

Preferably, the adjacent transistors may enclose an angle of greater than 0°.

The adjacent transistors can preferably extend in different spatial directions (e.g. along an X, Y or Z axis).

According to another embodiment, the multilevel converter system is constructed as PECIN, MMSPC, M2B or BM3.

In this case, the topology PECIN stands for “Parallel Enhanced Commutation Integrated Nested”, MMSPC stands for “Modular Multilevel Series Parallel Converter” and M2B stands for “Modular Multilevel Battery”.

BM3, which is also called a Marx topology, stands for “Battery Modular Multilevel Management”.

In principle, other topologies, e.g. half-bridge, prior half-bridge, cross-switched, cascaded cross-switched, CEBS, full-bridge, or ECIN, are also conceivable.

The topologies mentioned are potential candidates for being installed in an electric vehicle, for example.

The invention relates to a method for producing a multilevel converter system according to the invention, in which N-conducting and P-conducting layers are produced in a wafer in such a way that the N-conducting and P-conducting layers are always arranged alternately, and/or in which P-conducting and N-conducting layers are produced in a wafer in such a way that the P-conducting and N-conducting layers are always arranged alternately.

In this way, at least two adjacent NPN transistors share an N-type zone or two adjacent PNP transistors share a P-type zone.

According to one embodiment, the wafer having an N-conducting layer is covered with a first non-conductive protective layer.

For example, a single-crystal silicon wafer or a single-crystal gallium wafer can be used as a starting point.

The first and/or the further protective layers may comprise or consist of silicon dioxide and/or gallium oxide, for example.

A first window is inserted into the first protective layer in order to produce a P-conducting layer.

The first window is covered with a second non-conductive protective layer.

A second window is inserted into the second protective layer in order to produce an N-conducting layer.

The second window is covered with a third non-conductive protective layer.

A third window is inserted into the third protective layer in order to produce a P-conducting layer.

The third window is covered with a fourth non-conductive protective layer.

A fourth window is inserted into the fourth protective layer in order to produce an N-conducting layer.

For example, an NPNPN transistor can be produced in this way.

This method can fundamentally be continued as desired.

Preferably, further windows are finally inserted and metallic connections are attached, e.g. vaporized.

A corresponding production method is also referred to as planar technology. The windows can be inserted, preferably etched, for example, by means of the so-called mask technique.

According to another embodiment, the wafer having a P-conducting layer is covered with a first non-conductive protective layer.

For example, a single-crystal silicon wafer or a single-crystal gallium wafer can be used as a starting point.

The first and/or the further protective layers may comprise or consist of silicon dioxide and/or gallium oxide, for example.

A first window is inserted into the first protective layer in order to produce an N-conducting layer.

The first window is covered with a second non-conductive protective layer.

A second window is inserted into the second protective layer in order to produce a P-conducting layer.

The second window is covered with a third non-conductive protective layer.

A third window is inserted into the third protective layer in order to produce an N-conducting layer.

The third window is covered with a fourth non-conductive protective layer.

A fourth window is inserted into the fourth protective layer in order to produce a P-conducting layer.

For example, a PNPNP transistor can be produced in this way.

This method can fundamentally be continued as desired.

Preferably, further windows are finally inserted and metallic connections are attached, e.g. vaporized.

A corresponding production method is also referred to as planar technology. The windows can be inserted, preferably etched, for example, by means of the so-called mask technique.

The invention further relates to a wafer for producing a multilevel converter system, in which N-conducting and P-conducting layers are always arranged alternately.

For example, the N-conducting and P-conducting layers may be arranged in such a way that an NPNPN structure is obtained.

Finally, the invention relates to a wafer for producing a multilevel converter system, in which P-conducting and N-conducting layers are always arranged alternately.

For example, the P-conducting and N-conducting layers may be arranged in such a way that a PNPNP structure is obtained.

All embodiments and components of the devices described herein are preferably designed to be produced according to one or more of the methods described herein. Furthermore, all embodiments of the devices described herein and all embodiments of the methods described herein can each be combined with each other, preferably also in a manner detached from the specific configuration in connection with which they are mentioned.

### BRIEF DESCRIPTION OF THE DRAWINGS

The invention is described by way of example below with reference to the drawings, in which:

FIG. 1 shows an embodiment of a multilevel converter system according to the prior art,

FIG. 2 shows a schematic illustration of three NPN transistors according to the prior art,

FIG. 3 shows a schematic illustration of an NPNPNPN transistor,

FIG. 4 shows a schematic illustration of a PECIN according to the prior art, and

FIG. 5 shows a schematic illustration of a PECIN according to the invention.

### DETAILED DESCRIPTION

First of all, it should be noted that the embodiments illustrated are of a purely exemplary nature. Thus, individual features can be implemented not only in the combination shown, but also alone or in other technically useful combinations. For example, the features of one embodiment can be combined in any desired manner with features of another embodiment. The configuration and/or number of energy storage modules, paths and transistors shown is/are purely exemplary and basically arbitrary.

If a figure contains a reference sign that is not explained in the directly related text of the description, reference is made to the corresponding preceding or subsequent comments in the description of the figures. The same reference signs are thus used for identical or comparable components in the figures and are not explained again.

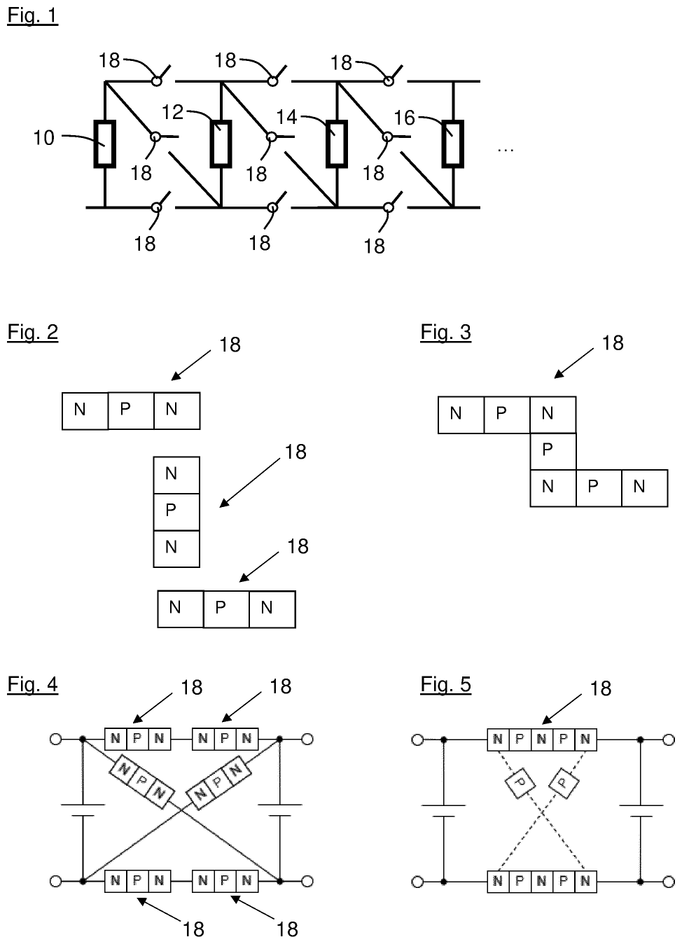

FIG. 1 shows a multilevel converter system having energy storage modules 10, 12, 14, 16.

Adjacent energy storage modules 10, 12, 14, 16 are each connected via a plurality of paths.

A switch in the form of a transistor 18 is provided in each path.

The adjacent energy storage modules 10, 12, 14, 16 can thus be connected in series or in parallel with each other. Individual energy storage modules 10, 12, 14, 16 can also be bridged if necessary, e.g. by closing the upper switch 18, and can thus be excluded from a configuration.

As illustrated in FIGS. 2 and 3, according to the invention, effectively three NPN transistors are combined to form an NPNPNPN transistor.

The adjacent NPN transistors each share an N-type zone.

The N-type zones can therefore be combined here. Although this increases the scrap rate somewhat, it makes the semiconductor smaller and cheaper. This can now be inserted into a housing, for example.

This can be implemented for all topologies. However, the effect is greatest with topologies that also allow connection in parallel and thus have more switches.

The NPNPNPN transistor is preferably inserted as a whole into a housing, which can also reduce the packaging costs.

FIGS. 4 and 5 show the combining of adjacent zones by way of example for a PECIN topology.

The two upper, horizontally arranged NPN transistors share an N-type zone and form an NPNPN transistor.

Likewise, the two lower, horizontally arranged NPN transistors share an N-type zone and form an NPNPN transistor.

The N-type zones of the two oblique NPN transistors are finally formed by the outer N-type zones of the horizontal NPNPN transistors. The dashed lines each represent an NPN connection in this case.

Between the two horizontal NPNPN transistors, an NPN transistor thus extends as it were from the left end of the upper NPNPN transistor to the right end of the lower NPNPN transistor, with the outer N-type zones being shared. A further NPN transistor extends from the right end of the upper NPNPN transistor to the left end of the lower NPNPN transistor, with the outer N-type zones being shared.

Similarly, it is also possible to provide PNP transistors in which adjacent PNP transistors share a P-type zone.

Costs can be saved by virtue of adjacent transistors each sharing a zone.

### LIST OF REFERENCE SIGNS

10 Energy storage module
12 Energy storage module
14 Energy storage module
16 Energy storage module
18 Transistor, switch

1. A multilevel converter system comprising
a multiplicity of energy storage modules (10, 12, 14, 16) and transistors (18), wherein each energy storage module (10, 12, 14, 16) can be connected in parallel with the respective adjacent energy storage module (10, 12, 14, 16), can be connected in series therewith and/or can be bridged and has at least one energy storage cell, wherein
at least two adjacent NPN transistors (18) share an N-type zone and/or wherein at least two adjacent PNP transistors (18) share a P-type zone.

2. The multilevel converter system as claimed in claim 1, wherein:
at least three NPN transistors (18) are provided, wherein adjacent NPN transistors (18) each share an N-type zone, and/or
at least three PNP transistors (18) are provided, wherein adjacent PNP transistors (18) each share a P-type zone.

3. The multilevel converter system as claimed in claim 1, wherein the adjacent NPN transistors (18) and/or PNP transistors (18) are arranged side by side.

4. The multilevel converter system as claimed in claim 1, wherein the adjacent NPN transistors (18) and/or PNP transistors (18) are not arranged linearly to each other.

5. The multilevel converter system as claimed in claim 1, wherein the multilevel converter system is constructed as PECIN, MMSPC, M2B or BM3.

6. A method for producing a multilevel converter system as claimed in claim 1, in which N-conducting and P-conducting layers are produced in a wafer in such a way that the N-conducting and P-conducting layers are always arranged alternately, and/or in which P-conducting and N-conducting layers are produced in a wafer in such a way that the P-conducting and N-conducting layers are always arranged alternately.

7. The method as claimed in claim 6, wherein:
a wafer with an N-conducting layer is covered with a first non-conductive protective layer,
a first window is inserted into the first protective layer in order to produce a P-conducting layer,
the first window is covered with a second non-conductive protective layer,
a second window is inserted into the second protective layer in order to produce an N-conducting layer,
the second window is covered with a third non-conductive protective layer,
a third window is inserted into the third protective layer in order to produce a P-conducting layer,
the third window is covered with a fourth non-conductive protective layer, and
a fourth window is inserted into the fourth protective layer in order to produce an N-conducting layer.

8. The method as claimed in claim 6, wherein:
a wafer with a P-conducting layer is covered with a first non-conductive protective layer,
a first window is inserted into the first protective layer in order to produce an N-conducting layer,
the first window is covered with a second non-conductive protective layer,
a second window is inserted into the second protective layer in order to produce a P-conducting layer,
the second window is covered with a third non-conductive protective layer,
a third window is inserted into the third protective layer in order to produce an N-conducting layer,
the third window is covered with a fourth non-conductive protective layer, and
a fourth window is inserted into the fourth protective layer in order to produce a P-conducting layer.

9. A wafer for producing a multilevel converter system as claimed in claim 1, in which
N-conducting and P-conducting layers are always arranged alternately.

10. A wafer for producing a multilevel converter system as claimed in claim 1, in which
P-conducting and N-conducting layers are always arranged alternately.
